(19) United States
(12) Patent Application Publication
(10) Pub. No.: US 2024/0038892 A1
(43) Pub. Date: Feb. 1, 2024

(54) DEVICE WITH TAPERED INSULATION STRUCTURE AND RELATED METHODS

(71) Applicant: Taiwan Semiconductor Manufacturing Company, Ltd., Hsinchu (TW)

(72) Inventors: Ya-Yi Tsai, Hsinchu (TW); Sheng-Yi Hsiao, Hsinchu (TW); Shu-Yuan Ku, Hsinchu (TW); Ryan Chia-Jen Chen, Hsinchu (TW)

(73) Assignee: Taiwan Semiconductor Manufacturing Company, Ltd., Hsinchu (TW)

(21) Appl. No.: 17/876,737

(22) Filed: Jul. 29, 2022

(51) Int. Cl. H01L 29/78; H01L 27/092; H01L 29/66; H01L 21/8238

(52) U.S. Cl. CPC H01L 29/7851; H01L 27/0924; H01L 29/66545; H01L 29/66795; H01L 21/823821; H01L 2029/7858

(57) ABSTRACT

A semiconductor device includes a transistor disposed in an active region. The transistor comprises a source/drain feature, a fin channel and a gate structure wrapping over the fin channel. The transistor also includes an insulation region disposed at an active edge. The active edge is at a boundary of the active region. The insulation region includes a trench. The trench has a tapered portion. A width of the tapered portion of the trench at a top of the fin channel is greater than a width of the tapered portion of the trench at a bottom of the gate structure.

### BACKGROUND

The present disclosure generally relates to semiconductor devices, and particularly to non-planar multigate semiconductor devices and methods of their making.

The electronics industry has experienced an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). Thus far these goals have been achieved in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). One such multi-gate device that has been introduced is the fin field-effect transistor (FinFET). The FinFET gets its name from the fin-like structure which extends from a substrate on which it is formed, and which is used to form the FET channel. FinFET devices are compatible with conventional complementary metal-oxide-semiconductor (CMOS) processes and their three-dimensional structure allows them to be aggressively scaled while maintaining gate control and mitigating SCEs.

To continue to provide the desired scaling and increased density for multi-gate devices in advanced technology nodes, continued reduction of the contacted poly pitch (CPP) (or “gate pitch”) is necessary. In at least some existing implementations, a continuous poly on diffusion edge (CPODE) process has been used to scale the CPP. By way of example, a CPODE process may be used to provide insulation between neighboring active regions (e.g., device regions including source, drain, and gate structures). However, existing CPODE techniques have not proved entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is illustrates a simplified top-down layout view of a multi-gate device.

FIG. 2 is a flow chart of a method of fabricating a multi-gate device, including a CPODE process.

FIG. 3A-I, FIG. 4A-F and FIG. 5A-H illustrate a known CPODE process for a metal gate.

FIG. 6A-H illustrate a known CPODE process for a dummy gate.

FIG. 7A-B illustrate dimensions for a dummy gate structure according to an embodiment.

FIG. 8A-8F illustrate a CPODE process according to an embodiment.

FIG. 9A-D provide comparison between an insulation structure produced by a known CPODE process and an insulation structure produced according to an embodiment.

FIG. 10A-C are electron microscope photographs of an insulation structure produced by a known CPODE process (10A) and an insulation structure produced according an embodiment before (10B) and after (10C) the structure is filled with a dielectric material.

FIG. 11A-D provide dimensions of an insulation structure produced according to an embodiment.

FIG. 12 illustrates a perspective view of a portion of a Fin Field-Effect Transistor (FinFET) device, in accordance with some embodiments.

FIG. 13A-13F illustrate cross-sectional views of a portion of an example FinFET device.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure relates to multi-gate transistors. Multi-gate transistors include those transistors whose gate structures are formed on at least two-sides of a channel region. These multi-gate devices may include a P-type metal-oxide-semiconductor device or an N-type metal-oxide-semiconductor multi-gate device. Specific examples may be presented and referred to herein as FinFET, on account of their fin-like structure.

Continuing to provide the desired scaling and increased density for multi-gate devices in advanced technology nodes calls for scaling of the contacted poly pitch (CPP) (or “gate pitch”). In at least some existing implementations, a continuous poly on fin edge (CPODE) process has been used to scale the CPP. For purposes of this disclosure, a “diffusion edge” may be equivalently referred to as an active edge, where for example an active edge abuts adjacent active regions. Further, an active region includes a region where transistor structures are formed (e.g., including source, drain, and gate/channel structures). In some examples, active regions may be disposed between insulating regions. The CPODE process may provide an insulation region between neighboring active regions, and thus neighboring transistors, by performing etching process along an active edge (e.g., at a boundary of adjacent active regions) to form a cut region and filling the cut region with a dielectric, such as silicon nitride (SiN).

Before the CPODE process, the active edge may include a structure having a gate and one or more of fins.

The CPODE process usually remove a fin and a portion of a substrate underneath the fin to provide an insulation between adjacent active regions. Such removal may involve etching aspect ratios of 20 or greater.

In some cases, source/drain epitaxial layers disposed next to a CPODE region may be damaged during a CPODE etching process, thereby compromising device performance and reliability. Thus, an alternative CPODE process that avoids damage to source/drain epitaxial layers may be desired.

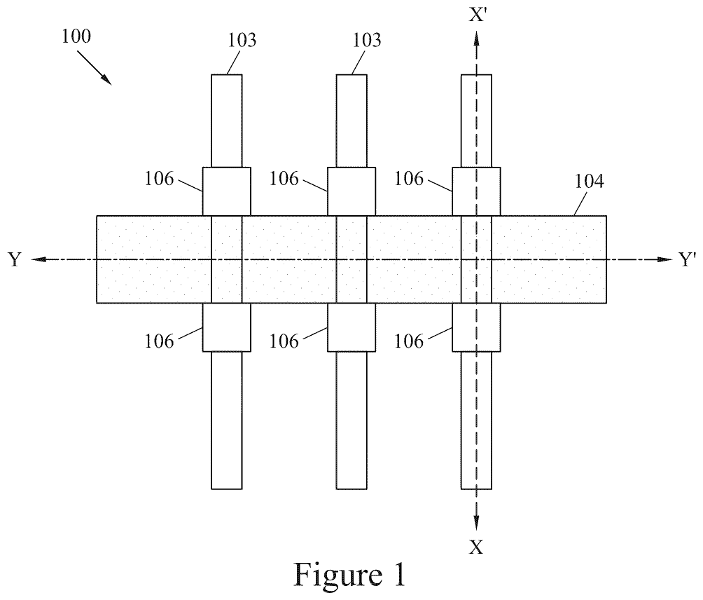

FIG. 1 provides a simplified top-down layout view of a multi-gate device 100. In various embodiments, the multi-gate device 100 may include a FinFET device, a GAA transistor, or other type of multi-gate device. The multi-gate device 100 may include a plurality of fin elements 103 extending from a substrate, a gate structure 104 disposed over and around the fin elements 104, and source/drain regions 106, where the source/drain regions 106 are formed in, on, and/or surrounding the fins 103 underlying the gate structure 104, along a plane substantially parallel to a plane defined by section X-X′ of FIG. 1.

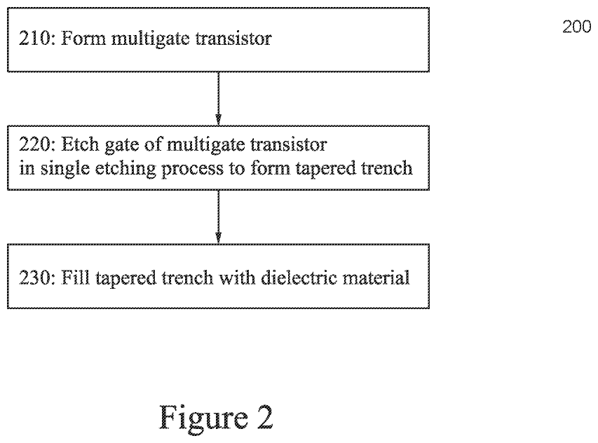

FIG. 2 illustrates method 200 of fabrication of a semiconductor device using a CPODE process. Method 200 includes operation 210: formation of a multigate device; operation 220, which is CPODE process of etching a gate of the multigate device to form a trench having a tapered shape. Etching 220 is performed in a single etching process for a material of the gate and an underlying fin and a substrate. Method 200 also includes operation 230 of filling the trench with a dielectric material.

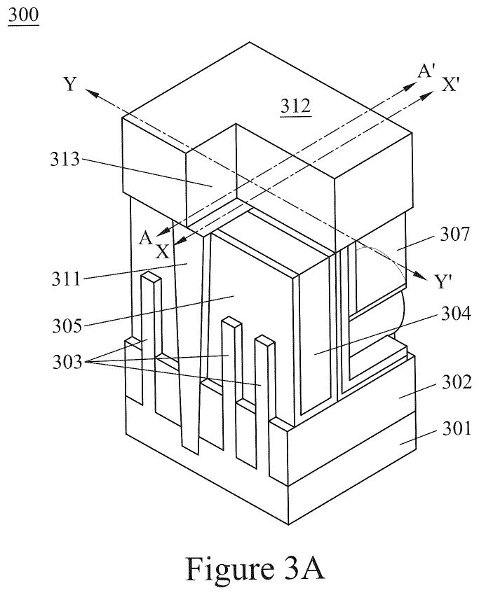

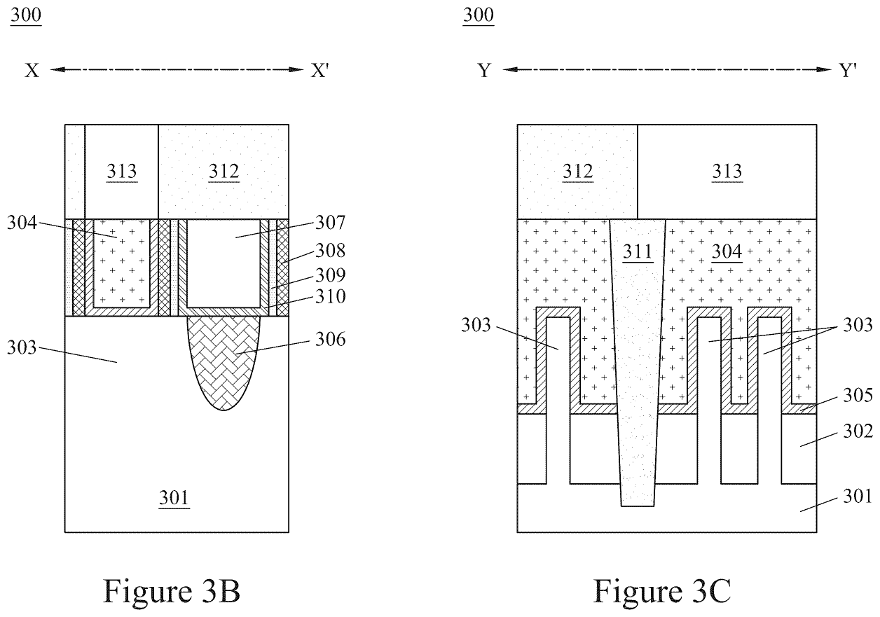

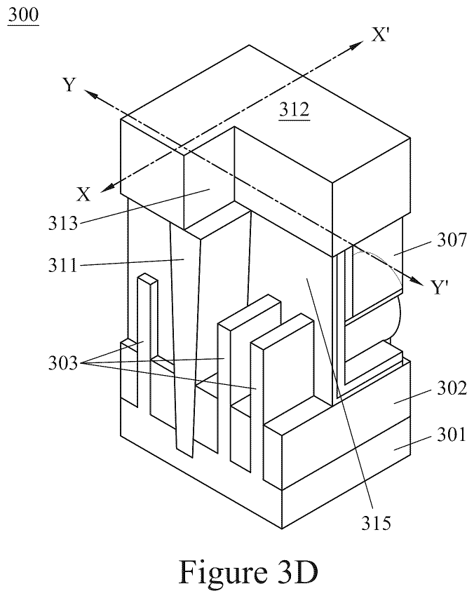

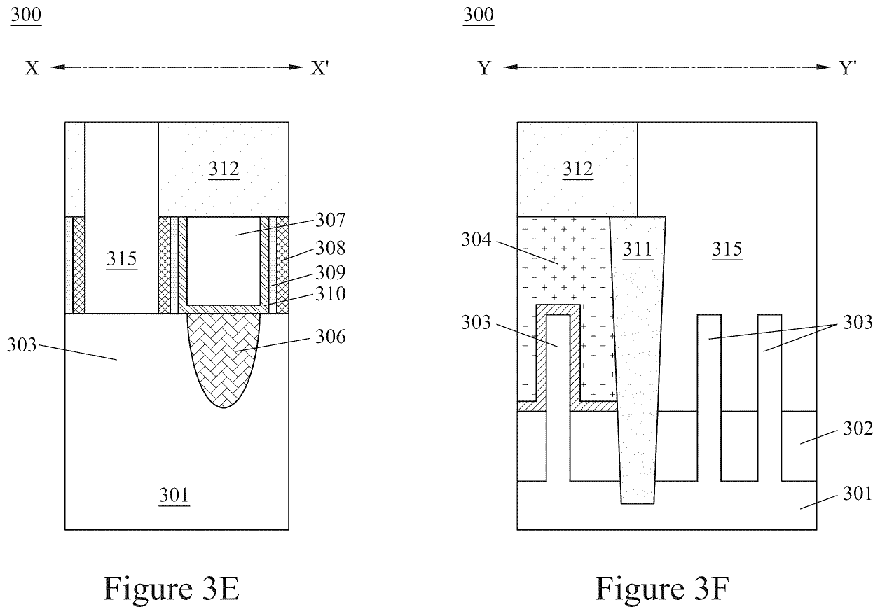

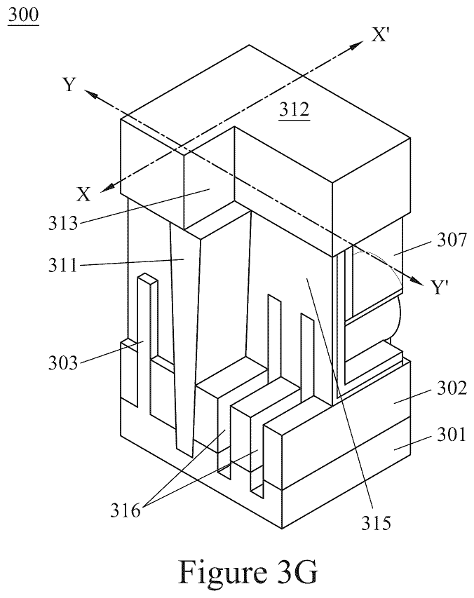

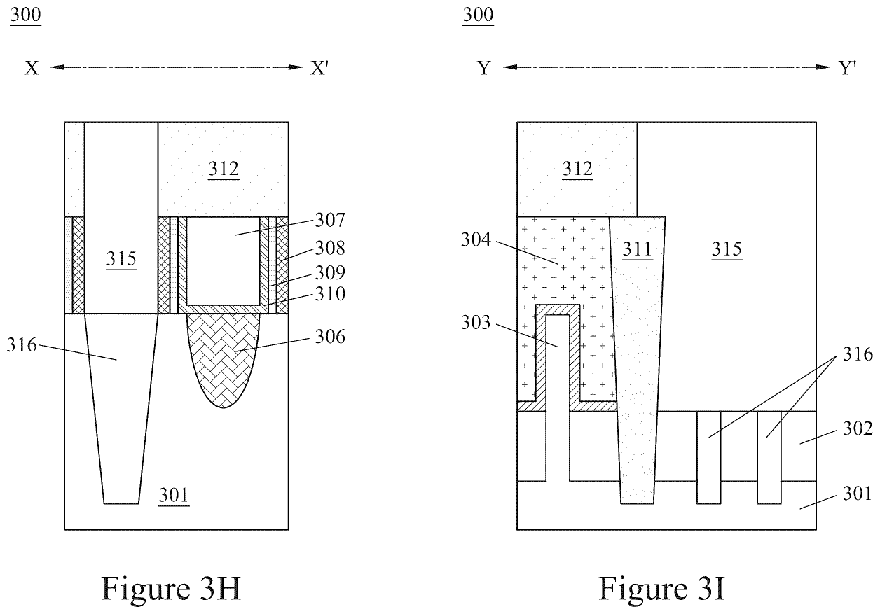

FIG. 3A-F show a known CPODE process. FIG. 3A provides a three dimensional view of Portion 300 of a FinFET device. Portion 300 includes substrate 301, shallow trench isolation (STI) 302 on substrate 301, plurality of fins 303 protruding from a surface of substrate 301 through STI 302, metal gate 304 wrapping along and over fins 303, high-k gate material 305; epitaxially grown source/drain 306, interlayer dielectric 307; spacers 308, 309 and 310; cut metal gate 311; hard mask layer 312. FIG. 3B corresponds to X-X′ cross-section on FIG. 3A through fin 303. FIG. 3C corresponds to Y-Y′ cross-section on FIG. 3A through metal gate 305. FIG. 3A-3C illustrate a first step of a CPODE process as forming opening 313 in hard mask layer 312 to expose metal gate 304 underneath hard mask layer 312.

The known CPODE process involves multistep etching, with an etching step for etching a material of the metal gate, such as metal gate 304, (“metal gate etching”) and an etching step for etching material(s) of the fin, such as fin 303, and the substrate, such as substrate 301, (“semiconductor etching”). For each of the metal gate etching and the semiconductor etching steps separate etching conditions are used depending on selectivity of a particular material etched in the particular etching step. During each of the metal gate etching and the semiconductor etching steps, a control of critical dimension enlargement and maintaining of the hard mask, such as hard mask 312, is also important for avoiding a damage to an interlayer dielectric, such interlayer dielectric 307, and an epitaxial source/drain, such as epitaxial source/drain 306.

FIG. 3D-F illustrate the metal gate etching step of the known CPODE process. FIG. 3D is a three dimension view similar to FIG. 3A, while FIG. 3E and FIG. 3F show respectively X-X′ and Y-Y′ cross-sections similar to those of FIG. 3B and FIG. 3C. As the result of etching metal gate 304 in the metal gate etching step, space 315 continuous with opening 313 is formed exposing fins 303.

FIG. 3G-I illustrate the semiconductor gate etching step of the known CPODE process. FIG. 3G is a three dimension view similar to FIG. 3A or FIG. 3D, while FIG. 3H and FIG. 3I show respectively X-X′ and Y-Y′ cross-sections similar to those of FIG. 3B (or FIG. 3E) and FIG. 3C (or FIG. 3C). As the result of etching fin 303 and substrate 301 in the semiconductor etching step, space 316 continuous with space 315 and opening 313 is formed. Space 316 extends into substrate 301. Space 316 together space 315 and opening 313 may be viewed as an insulation trench at an active edge of an active region, which may include epitaxial source/drain 306 and interlayer dielectric 307. On the other side of such trench to the left on the trench on FIG. 3H, there may be another active region with an epitaxial source/drain similar to epitaxial source/drain 306.

FIGS. 4A, 4B, 4C, 4D, 4E and 4F essentially correspond to FIGS. 3B, 3C, 3E, 3F, 3H and 3I respectively.

FIG. 5A-H also illustrate the known CPODE process. FIGS. 5A, 5C, 5E and 5G show X-X′ cross-sections, while FIGS. 5B, 5D, 5F and 5H show corresponding A-A′ cross-sections. As shown in FIG. 3A A-A′ cross-section is parallel to X-X′ cross-section, while being cut not through fin 303 and epitaxial source/drain 306 but through STI 302 and interlayer dielectric 307. FIGS. 5A and 5B shows device 300 before opening 313 is formed in hard mask layer 312. FIGS. 5C and 5D shows device 300 after opening is formed in hard mask layer 312. As such FIG. 5C presents the same view as FIG. 3B. FIGS. 5E and 5F show device 300 after the metal gate etching step of the known CPODE process. As such FIG. 5E presents the same view as FIG. 3E. FIGS. 5G and 5H show device 300 after the semiconductor etching step of the known CPODE process. As such FIG. 5G presents the same view as FIG. 3H. In FIGS. 5G and FH space 316 together space 315 and opening 313 form insulation trench 317 at an active edge of an active region, which may include epitaxial source/drain 306 and interlayer dielectric 307.

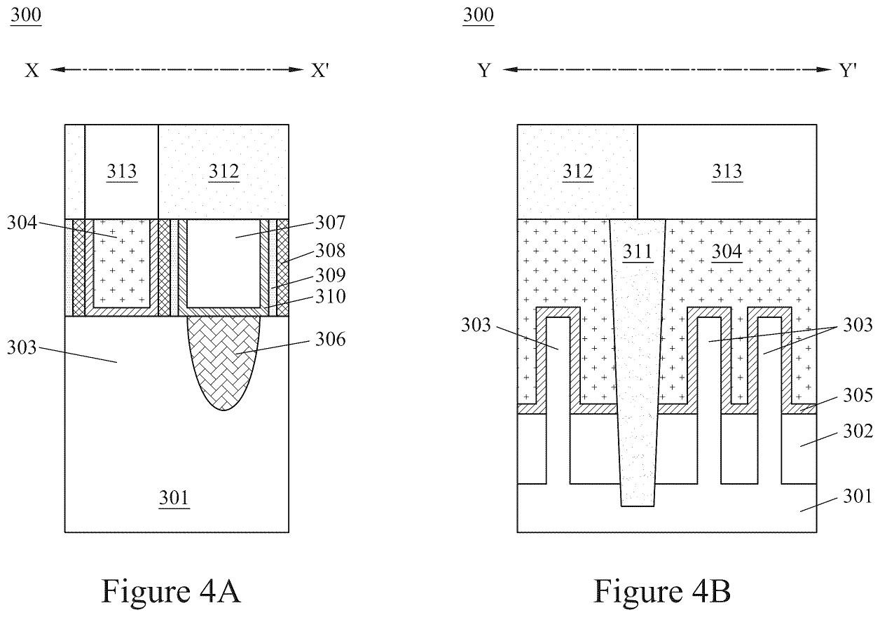

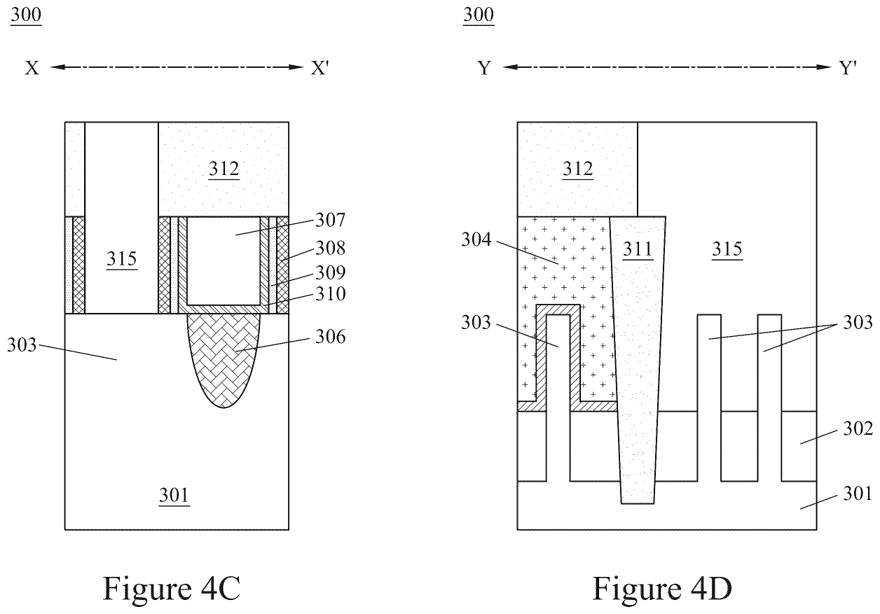

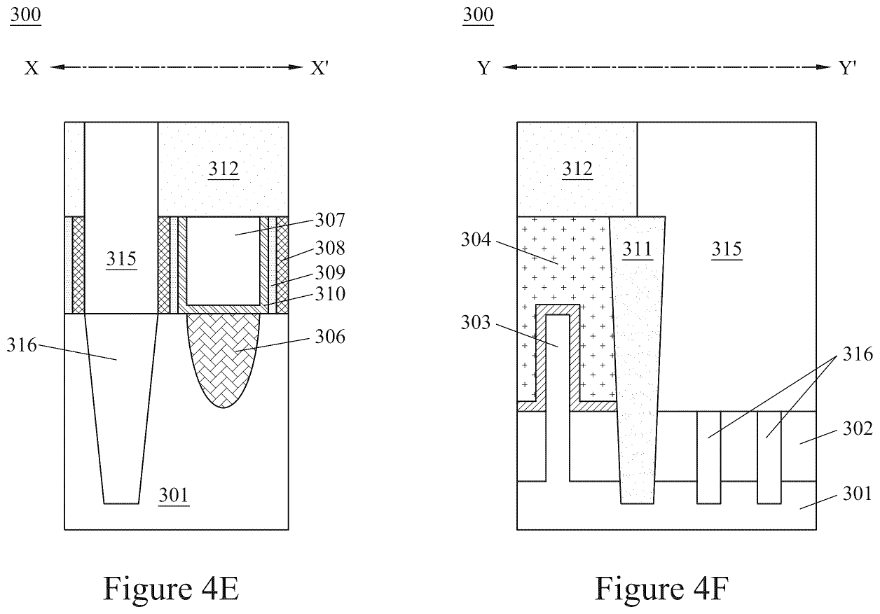

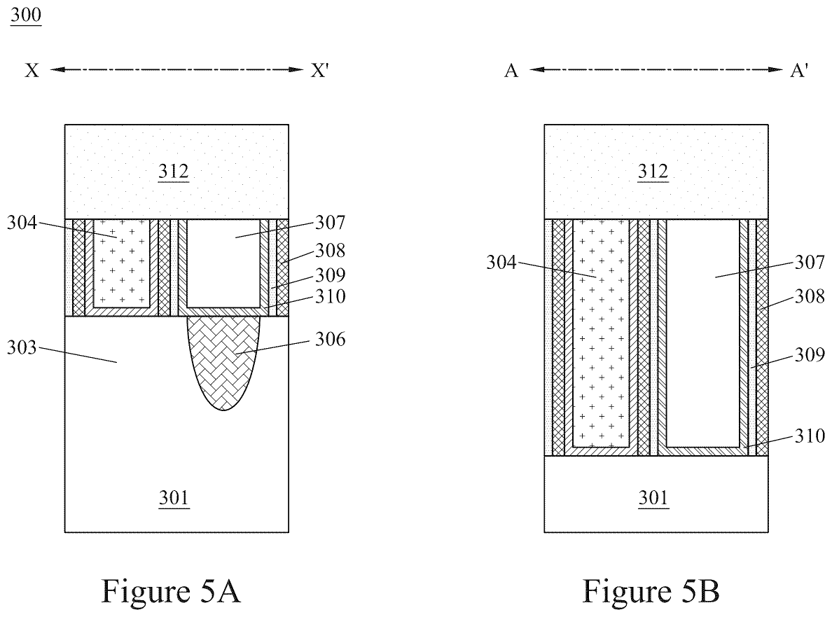

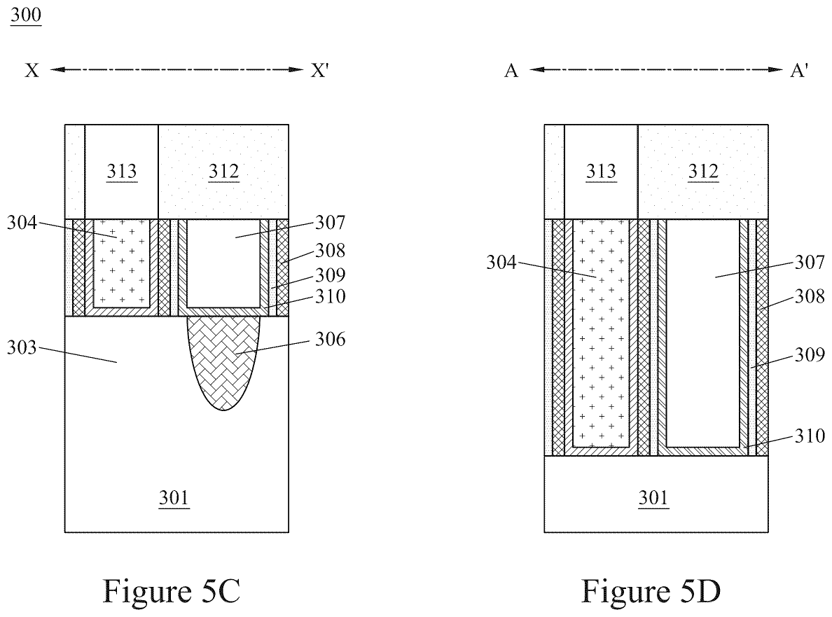

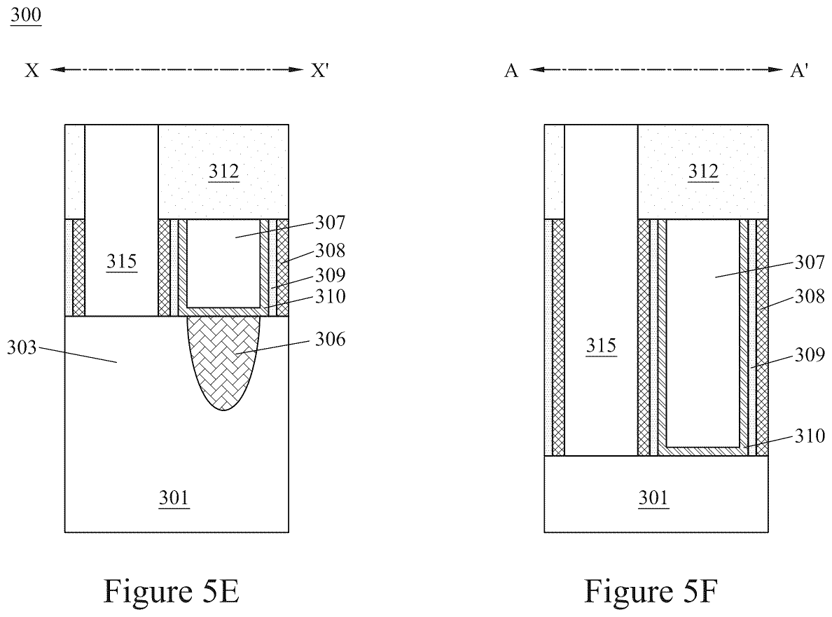

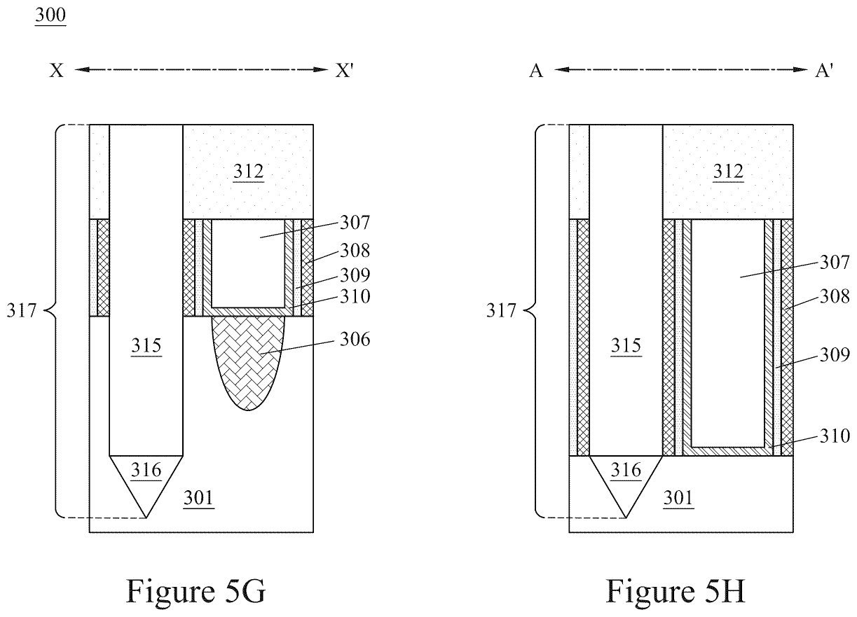

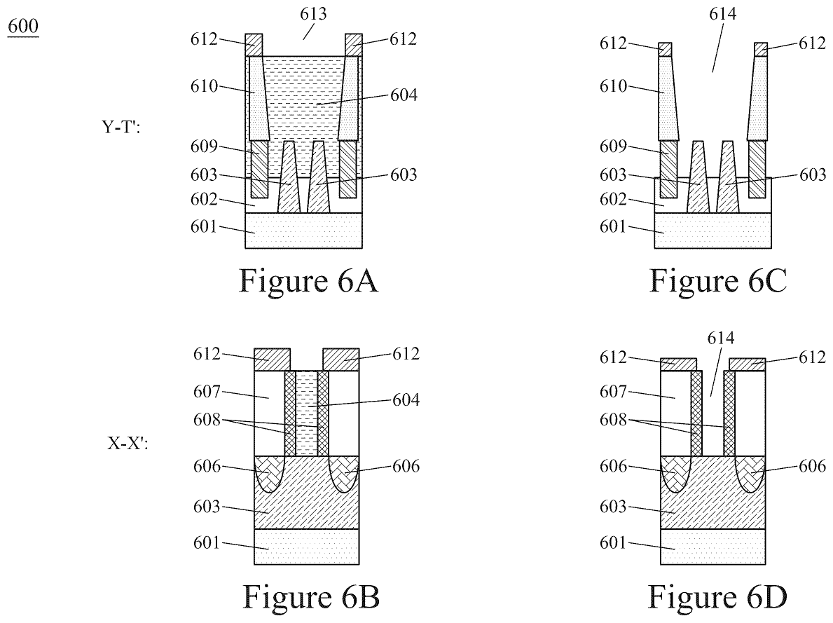

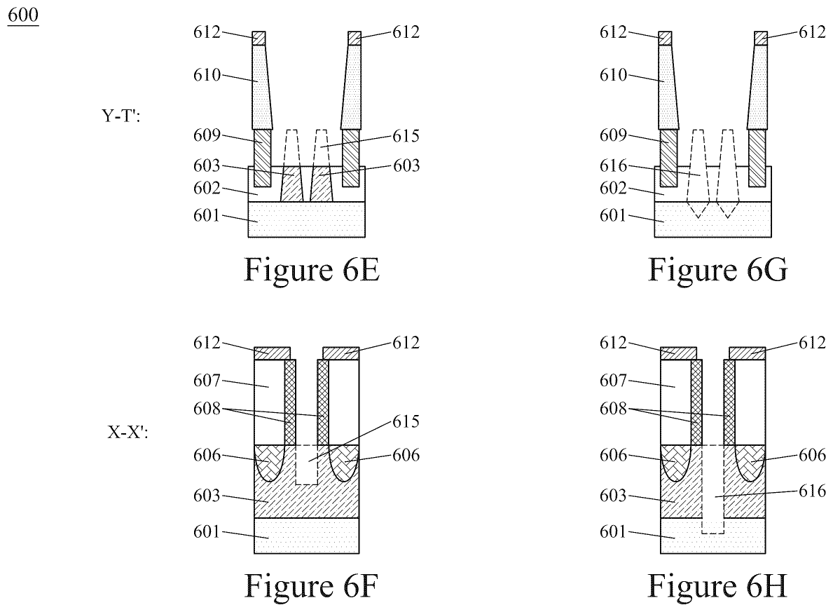

FIG. 6A-H illustrate a known CPODE process for portion 600 of a FinFET device with a dummy gate instead of a metal gate. The known CPODE process involves multiple etching steps. In FIGS. 6A and 6B, portion 600 includes substrate 601, shallow trench isolation (STI) 602 on substrate 601, plurality of fins 603 protruding from a surface of substrate 601 through STI 602, dummy gate 304 wrapping along and over fins 303, dielectric layers 609 and 610; epitaxially grown source/drain 606, one or more dielectric and/or spacer layers 608; hard mask layer 612. Hard mask layer 612 has opening 613. FIGS. 6C and 6D illustrate a first step of the multistep etching, which removes dummy gate 604, while exposing top parts of fins 603. Space 614 is formed as the result of removal of dummy gate 604. FIGS. 6E and 6F illustrate a second step of the multistep etching, which removes top parts of fins 603 and as the result creates space 615. FIGS. 6E and 6F illustrate a third step of the multistep etching, which removes bottom parts of fins 603 and portions of substrate 601 underneath fins 603, creating as the result space 616. Spaces 614, 615, 616 together with opening 613 form a trench, which may serve as an insulation region or structure of the FinFET device. An aspect ratio of the first and second etching steps may be from 1 to 60. An aspect ratio for third etching step may be from 2 to 100.

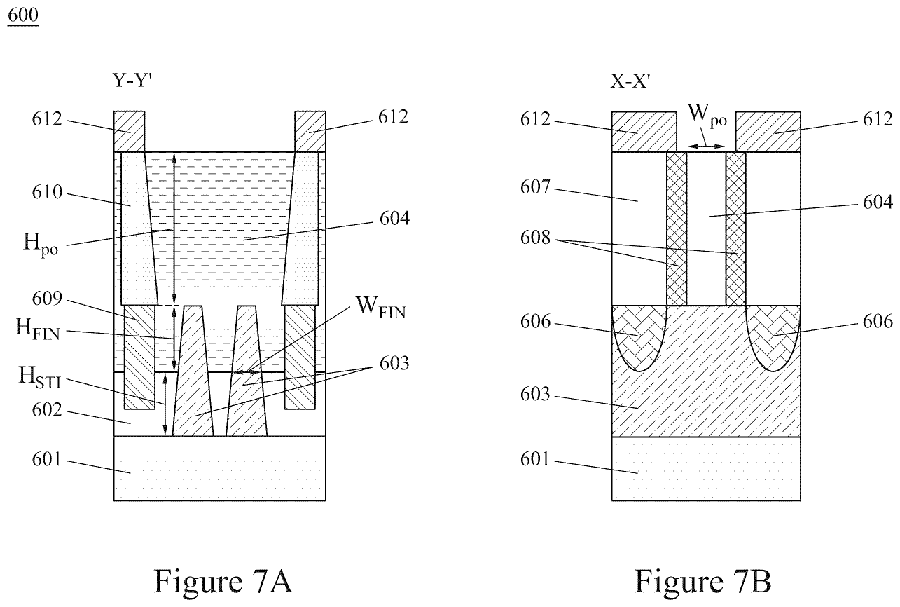

FIG. 7A-H show exemplary dimensions for a FinFET device with a dummy gate. A height of a fin 603 (H_{FIN}) may be from about 50 Å to about 1000 Å. A height of a polysilicon dummy gate material 604 (H_{PO}) may be from about 50 Å to about 2000 Å. A height of STI 602 (H_{STI}) may be from about 50 Å to about 1000 Å. A width of polysilicon dummy gate materials 604 between spacer layers 608 in X-X′ cross-section (W_{PO}) may be from about 50 Å to about 1000 Å. A width of fin 603 at the top of STI 602 in the Y-Y′ cross-section (W_{FIN}) may be from about 20 Å to 500 Å.

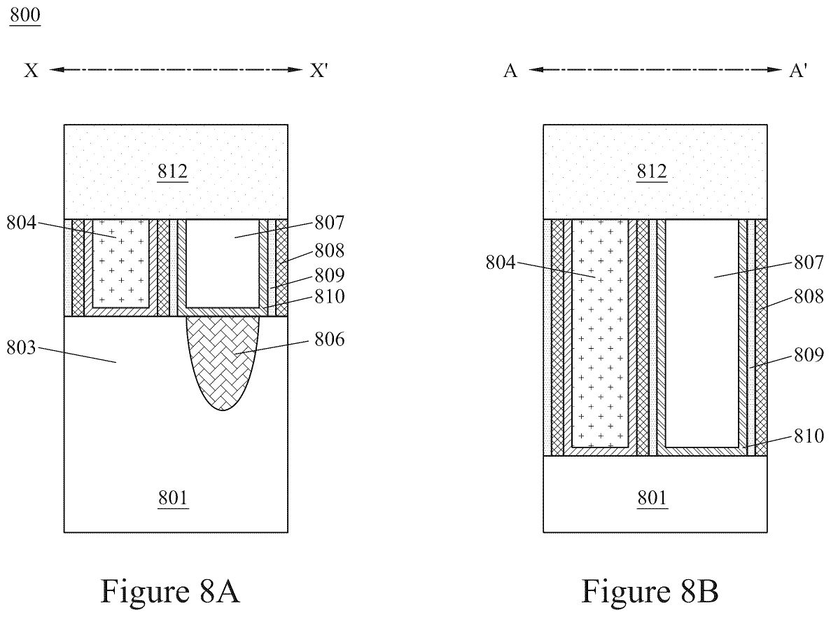

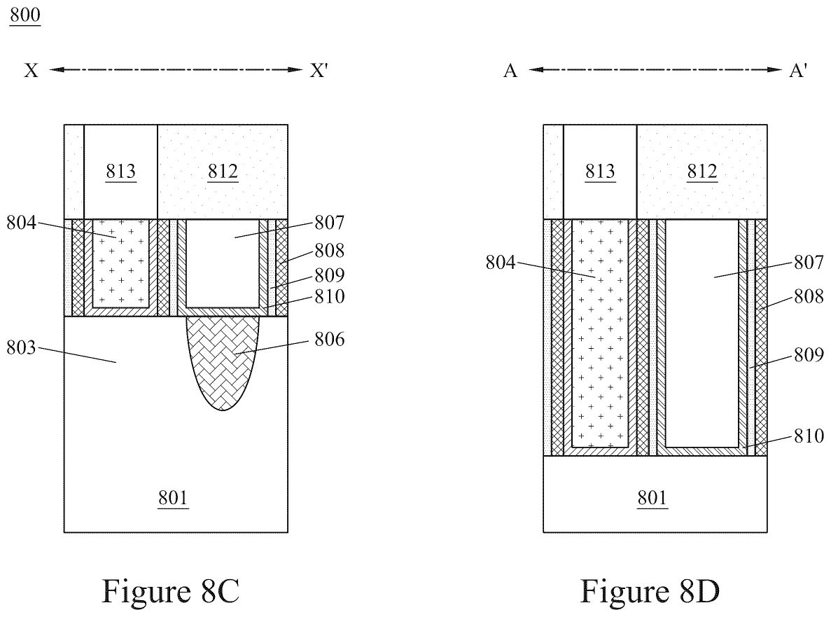

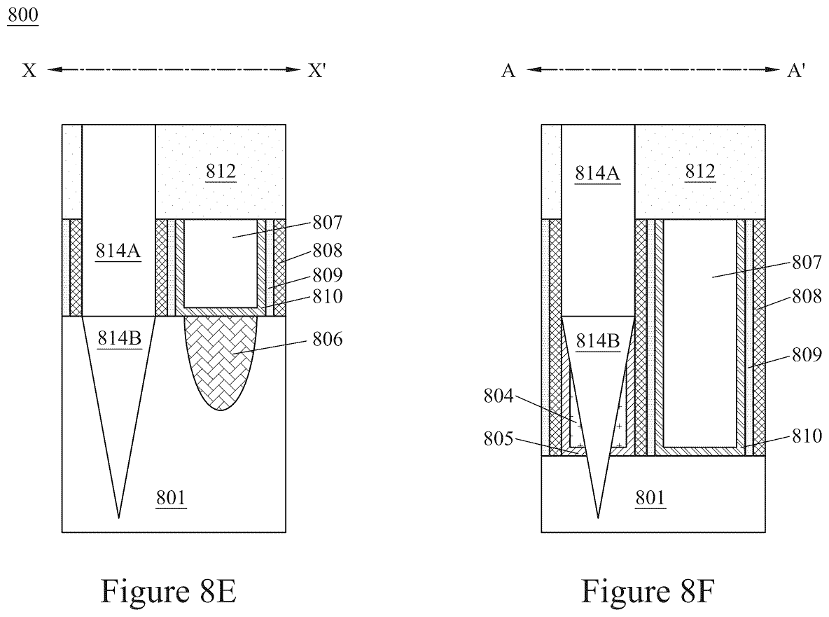

FIG. 8A-F shows a CPODE process according to one of the embodiments. FIG. 8A-F show FinFET device 800, which may be the same or similar to FinFET device 300 prior to the metal gate etching step of the known CPODE process. FIGS. 8A, 8C, and 8E show X-X′ cross-sections as defined in FIG. 3A for device 300, while FIGS. 8B, 8D and 8F show corresponding A-A′ cross-sections as defined in FIG. 3A for device 300.

Similar to device 300, device 800 includes substrate 801, shallow trench isolation (STI) 802 on substrate 801, plurality of fins 803 protruding from a surface of substrate 801 through STI 802, metal gate 804 wrapping over fins 803, high-k gate material 805; epitaxially grown source/drain 806, interlayer dielectric 807; spacers 808, 809 and 810; and hard mask layer 812.

FIG. 8A-D present essentially the same views as FIG. 5A-D. FIGS. 8A and 8B shows device 800 before opening 813 is formed in hard mask layer 812. FIGS. 8C and 8D shows device 800 after opening is formed in hard mask layer 812.

FIGS. 8E and 8F show a formation of trench 814, which consists of portions 814A and 814B. Trench 814, including its portions 814A and 814B, are formed in a single continuous etching step using the same etching process, such as a dry etching process. The dry etching may be performed using one or more etching gases, such as Cl₂, BCl₃, HBr, CF₄ and C₄F₆. In some embodiments, one or more additional gases, such as N₂, O₂, SiCl₄, CH₄, CHF₃, C₂H₂, CH₃F may be added to the etching gas(es). Such additional gas(es) may generate sidewall protection, such as polymeric sidewall protection, for the trench, which may facilitate formation of the taper profile of the trench. Trench 814, including portions 814A and 814B, extends in Y-Y′ direction. Portion 814A, which is formed by removing a portion of metal grate material 804 over gate 803, has a straight (or bowing profile). High-k gate dielectric 805 stays intact around portion 814A. Portion 814B which extends through fin 803 and substrate 801 in the through-fin cross-section X-X′ in FIG. 8E, has a tapered shape. Due to the tapered shape of portion 814B, some residual metal gate material 804 and residual high-k dielectric material 805 remain in the through-STI cross-section A-A′ as shown in FIG. 8F. Trench 814 with straight (or bowing) portion 814A and tapered portion 814B may be formed in the single etching process by controlling the etch profile. In some embodiments, unfilled trench 814 may be used as an insulation structure. Yet in some embodiments, trench 814 may be filled with a dielectric material, such as silicon nitride.

The CPODE process illustrated in FIG. 8A-F may provide an improvement of yield for making semiconductor devices because it may prevent damage to epitaxial source/drain. A damage to epitaxial source/drain may lead to an increased resistance as well as to yield losses. The CPODE process illustrated in FIG. 8A-F may also enlarge process window. In the known CPODE process, the distance between an isolating trench and epitaxial source/drain may be equal to a thickness of spacers, such as spacers 308/309. Therefore, the known CPODE process may need a more precise overlay patter control, that may be smaller than the spacer thickness. Similarly, in the known CPODE process, the opening critical dimension of CPODE trench may be also limited by the same distance. The CPODE process illustrated in FIG. 8A-F may provide more flexibility compared to the known CPODE process. For example, because the CPODE process illustrated in FIG. 8A-F has a larger window, which prevents damage to epitaxial source/drain, compared to that of the known CPODE process, the CPODE process illustrated in FIG. 8A-F may provide larger operation window (control) for parameters of a CPODE process such as critical dimensions of polysilicon, spacer thickness, photo overlay pattern, and CPODE opening critical dimensions due to less strict requirements for those parameters.

Although the CPODE process illustrated in FIG. 8A-F for a portion of a FinFET device with a metal gate wrapping along and over a fin, a similar CPODE process with a single continuous etching process may be applied to a portion of a FinFET device with a dummy gate wrapping along and over a fin, such as portion 600 in FIG. 6A-B.

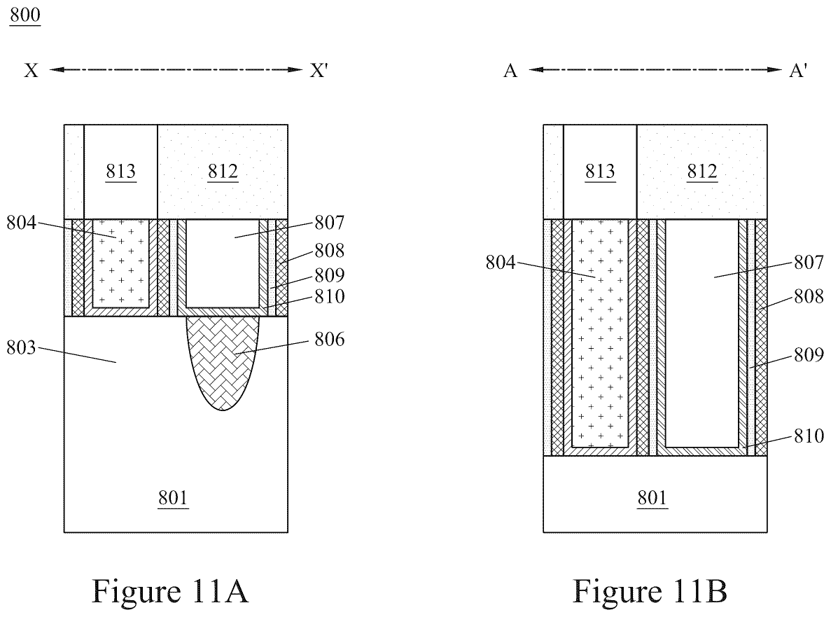

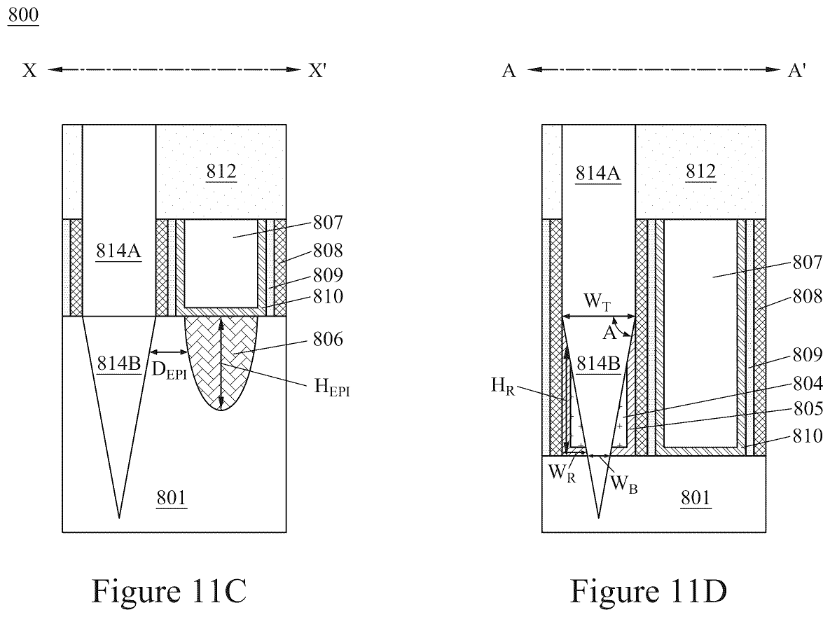

FIG. 11A-D correspond to FIG. 8C-F, while providing additional dimensional information, including dimensional information for trench 814. As shown in FIG. 11D, W_{T}, which is a width (i.e. a dimension perpendicular to Y-Y′ direction and perpendicular to a direction in which fin 803 protrudes from substrate 801, i.e. a fin height direction) of trench 814 at top of fin 803, is greater than W_{B}, which is a width at the bottom of metal gate 804 or at the bottom of high-k dielectric 805. In FIG. 11D, W_{B} is shown as a width at the bottom of high-k dielectric 805 for illustrative purposes only. Considering that differences between a width at the bottom of metal gate 804 or a width at the bottom of high-k dielectric 805 are not substantial compared to differences between W_{B} and W_{T} for the sake of simplicity, W_{B} is referred in this disclosure as the width at gate bottom. Width at fin top (W_{T}) may be from 50 Å to about 1000 Å or any value or subrange within this range. Width at gate bottom (W_{B}) may be from about 5 Å to about 1000 Å or any value or subrange within this range. An angle of trench 814 (A), i.e. an angle between a tapered wall of tapered portion 814B and a horizontal direction perpendicular to Y-Y′ direction and perpendicular to a direction in which fin 803 protrudes from substrate 801 maybe from about 45 degrees to less than about 90 degrees or from about 45 degrees to about 80 degrees or any value or subrange within these range. A height of EPI (HEN), i.e. a height of epitaxial source drain 806, may be from about 50 Å to about 1000 Å or any value or subrange within this range. A distance between trench to EPI (D_{EPI}), i.e. a distance from a tapered wall of tapered portion 814B of trench 814 to epitaxial source/drain 806, at ½ H_{EPI} may be from about 1 Å to about 510 Å or any value or subrange within this range. A height of remain (H_{R}), i.e. a height of residual metal gate 804 and/or residual high-k dielectric 805 remaining after etching resulting in formation trench 814 with tapered portion 814B, may be from about 1 Å to about 2000 Å or any value or subrange with this range. A width of remain (W_{R}), i.e. a width of residual metal gate 804 and/or residual high-k dielectric 805 up to tapered wall of tapered portion 814B, is from about 1 Å to about 500 Å. W_{R} and H_{R} on left and right sides of the trench 814 may be the same or different.

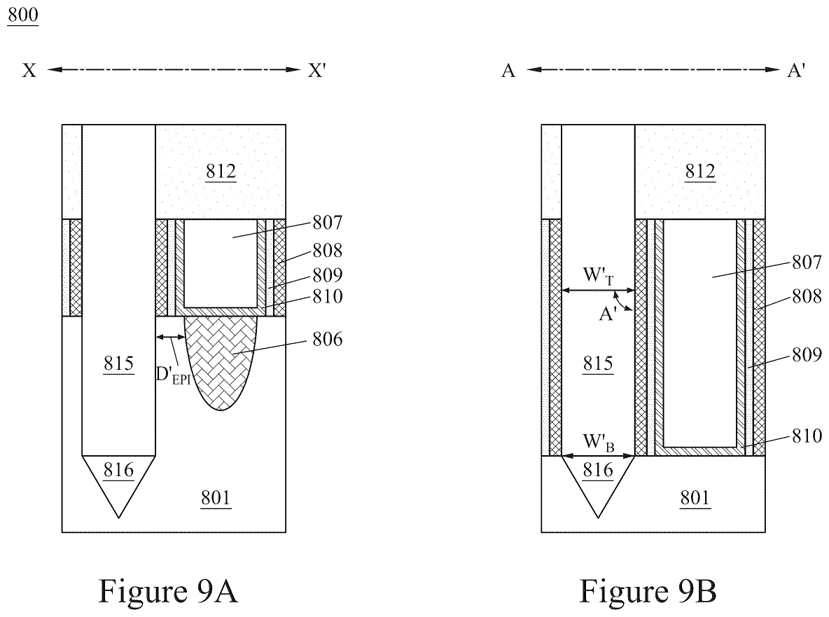

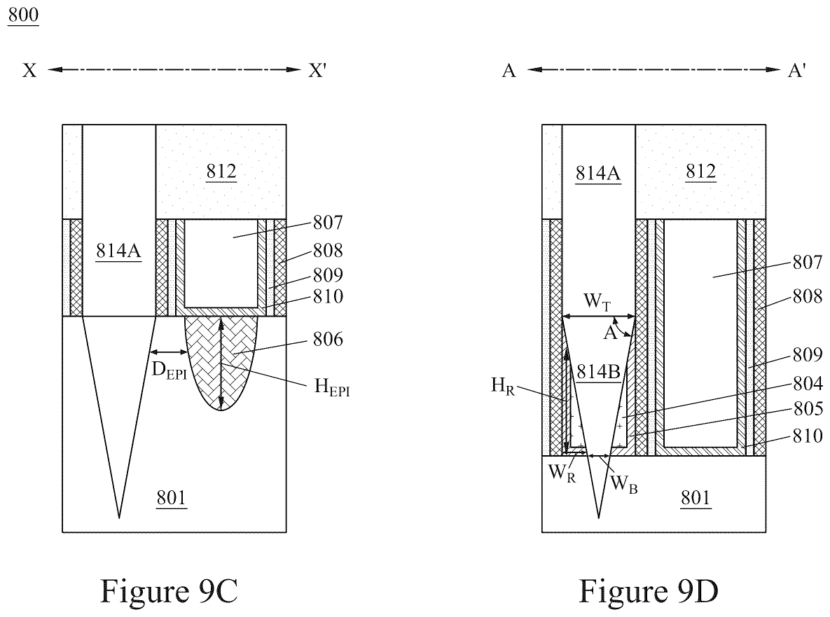

FIGS. 9C and 9D present dimensions of trench 814 having tapered portion 814 in comparison with trench 317 in FIGS. 9A and 9B formed by the known CPODE method with the multi-step etching. FIGS. 9C and 9D correspond to FIGS. 8E and 8F (or FIGS. 11C and 11D), while FIGS. 9A and 9B correspond to FIGS. 5G and 5H. W_{B}′, W_{T}′, A′ and D′EPI in FIGS. 9A and 9B may be defined similar to W_{B}, W_{T}, A and DEPT in FIGS. 11C and 11D. In FIGS. 9A and 9B for the trench formed by the known CPODE method with the multi-step etching W′_{B}≥W′T. This is different from trench 814 with tapered portion 814 B in FIGS. 9C and 9D for which W_{B}<W_{T}. In FIGS. 9A and 9B for the trench formed by the known CPODE method with the multi-step etching A′ is about 90 degrees. This is different from trench 814 with tapered portion 814 B in FIGS. 9C and 9D, for which A is from about 45 degrees to less than about 90 degrees or from about 45 degrees to about 80 degrees. In FIGS. 9A and 9B for the trench 317 formed by the known CPODE method with the multi-step etching D′_{EPI} is from 1 A to 500 A. D_{EPI} in FIGS. 9C and 9D trench 814 with tapered portion 814 B can be greater than D′_{EPI} in FIGS. 9A and 9B due to the tapered shape of the trench 814, which means a better protection against damage for epitaxial source drain layer.

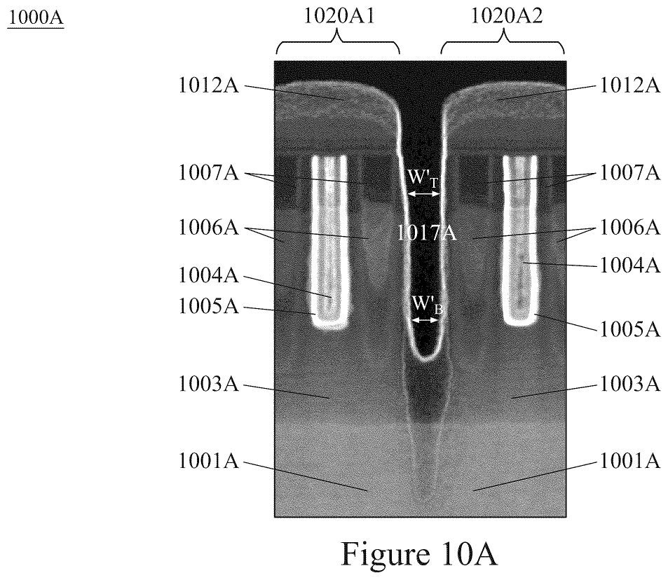

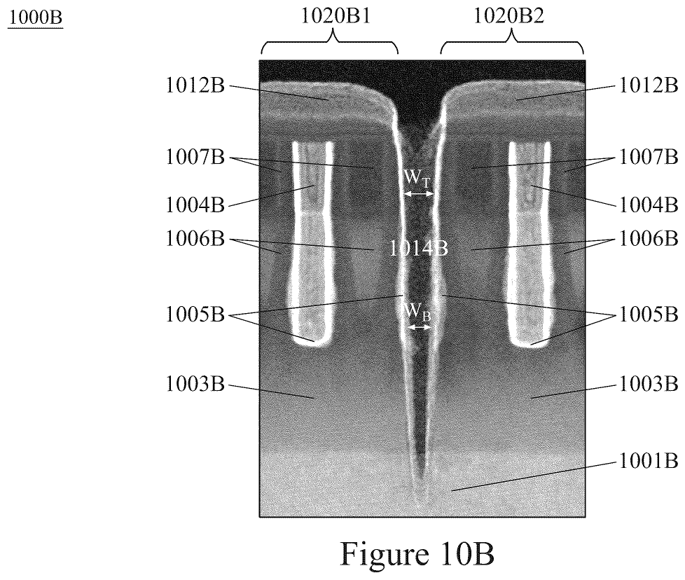

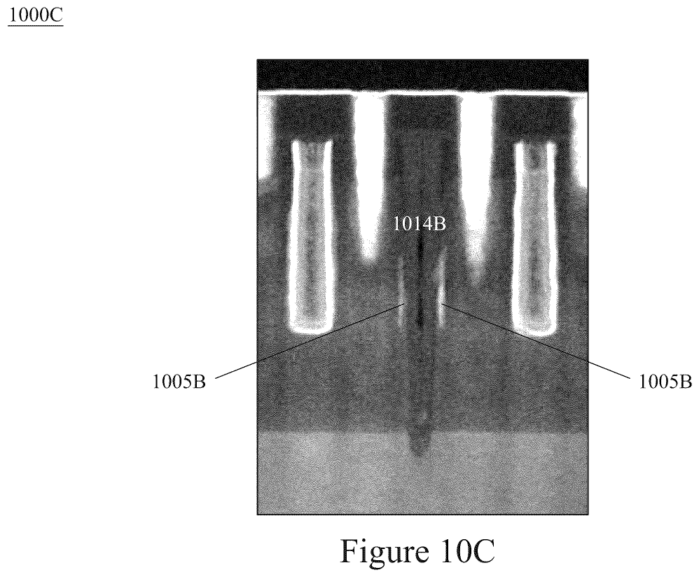

FIG. 10B shows an electron microscope photograph of a portion of multigate device 1000B with tapered shape trench 1014B according to an embodiment. FIG. 10C is an electron microscope photograph of multigate device 1000B with tapered shape trench 1014B filled with dielectric material 1014C, which may be silicon nitride, silicon oxide or a mixture thereof. FIG. 10A shows an electron microscope of a portion of multigate device 1000A with trench 1017A formed according to the known CPODE process with a multistage etching.

FIG. 10B shows trench 1014B having a tapered shape formed at an active edge between two active regions 1020B1 and 1020B2. Each of active regions 1020B1 and 1020B2 includes fin channel 1003B (similar to fin 803) protruding from substrate 1001B (similar to substrate 801); metal gate 1004B (similar to metal gate 804) wrapped over fin channel 1003B; epitaxial source/drain 1006B (similar to epitaxial source drain 806) in fin channel 1003B. Each of active regions 1020B1 and 1020B2 also includes high-k gate dielectric 1005B around metal gate 1004B, interlayer dielectric 1007B (over epitaxial source/drain 1006B). FIG. 10B also shows top hard mask layer 1012B. Trench 1014B having a tapered shape is formed after forming an opening in hard mask layer 1012B by a single continuous etching process. Before the etching the area of trench 1014B included a metal gate (similar or identical to metal gate 1004B) surrounded by a high-k gate dielectric (similar or identical to metal gate 1004B). The single continuous etching process forming trench 1014B etched away that metal gate together with portions of fin channel 1003B and substrate 1001B. The single continuous etching process leaves some residual material of the metal gate and the high-k gate dielectric along tapered side walls of trench 1014B. Photographs of FIGS. 10B and 10C show remaining high-k gate dielectric 1005B along tapered side walls of trench 1014B. Trench 1014B has a tapered shape with its width, W_{T}, at the top of fin 1003B being greater than its width, W_{B}, at the bottom of metal gate 1004B. As shown in FIG. 10B, the single continuous etching process forming trench 1014B does not damage either epitaxial source/drain 1006B of either of adjacent active regions 1020B1 and 1020B2 or interlayer dielectric layer 1007B over epitaxial source/drain 1006B.

FIG. 10A shows trench 1017A between two active regions 1020A1 and 1020A2. Each of active regions 1020A1 and 1020A2 includes fin channel 1003A (similar to fin 303) protruding from substrate 1001A (similar to substrate 301); metal gate 1004A (similar to metal gate 304) wrapped over fin channel 1003A; epitaxial source/drain 1006A (similar to epitaxial source drain 306) in fin channel 1003A. Each of active regions 1020A1 and 1020A2 also includes high-k gate dielectric 1005A around metal gate 1004A and top hard mask layer 1012A. Trench 1017A is formed by the known CPODE process, which involves an opening in hard mask layer 1012A, and a multistep etching process. Before the CPODE process, the area of trench 1017A included a metal gate (similar or identical to metal gate 1004A) surrounded by a high-k gate dielectric (similar or identical to metal gate 1004A). The multistep etching process involves (a) first performing metal gate etching, i.e. etching metal gate 1004A and (b) then performing a separate semiconductor gate etching, i.e. etching portions of fin 1003A and substrate 1001A. Trench 1017A has a bowing profile with its width, W_{B}, at the bottom of metal gate 1004A, being the same as or greater than its width, W_{T}, at the top of fin 1003A.

The photographs in FIG. 10A-C present images perpendicular to the Y-Y′ direction, while presenting more information than illustrative cross-sections X-X′ and A-A′. For example, these photographs show fin channel(s), epitaxial source/drain(s) and metal gate(s) at the same time.

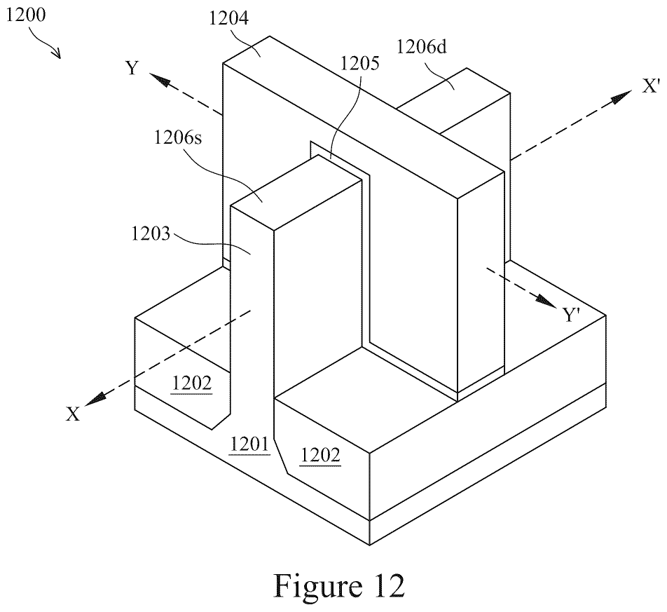

FIG. 12 illustrates a perspective view of an single gate portion 1200 of a multigate FinFET device. Device portion 1200 includes a substrate 1201 and a fin 1203 protruding above the substrate 1201. Isolation regions 1202 are formed on opposing sides of the fin 1203, with the fin 1203 protruding above the isolation regions 510. A gate dielectric 1205 is along sidewalls and over a top surface of the fin 1203, and a gate 1204 is over the gate dielectric 1205. Source/drain structures 1206S and 1206D are in (or extended from) the fin 1203 and on opposing sides of the gate dielectric 1205 and the gate 1204. The multigate FinFET device include multiple, i.e. two or more, single gate portions similar to single gate portion 1200. Each of such single gate portions includes a gate dielectric, which is similar to gate dielectric 1205, along sidewalls and over a top surface fin 1203 and a gate, which is similar to gate 1204, over the gate dielectric. The multigate FinFET device may include multiple, i.e. two or more, fins with gate dielectric 1205 along sidewalls and over a top surface of each of the fins and gate 1204 is over the gate dielectric 1205. For example, FIG. 1 shows a simplified top-down layout view of such multigate device with gate 104 being over each of plural fins 103

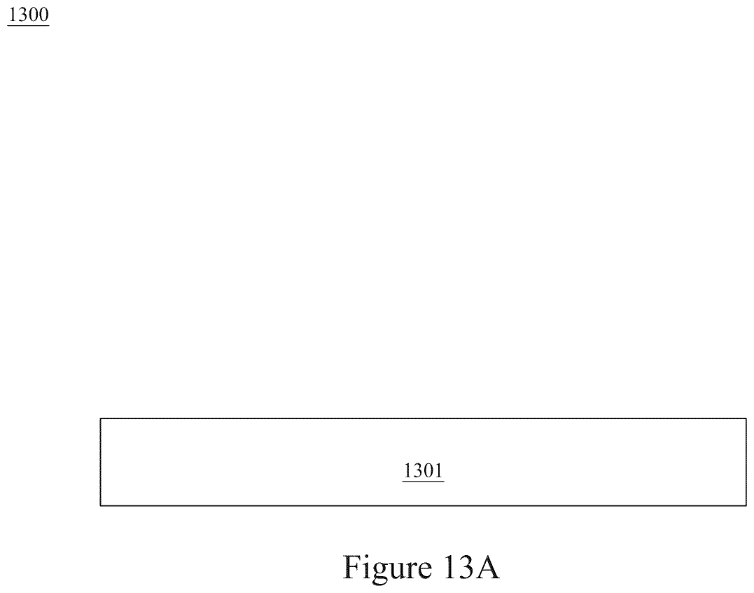

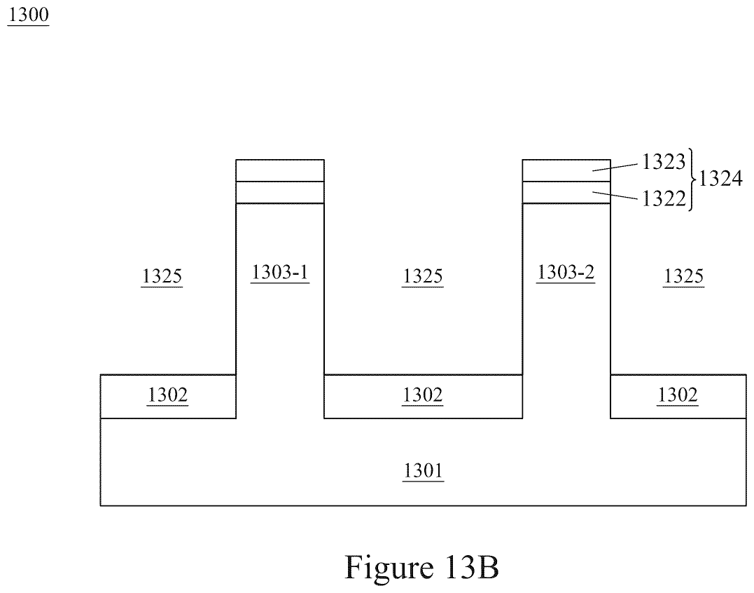

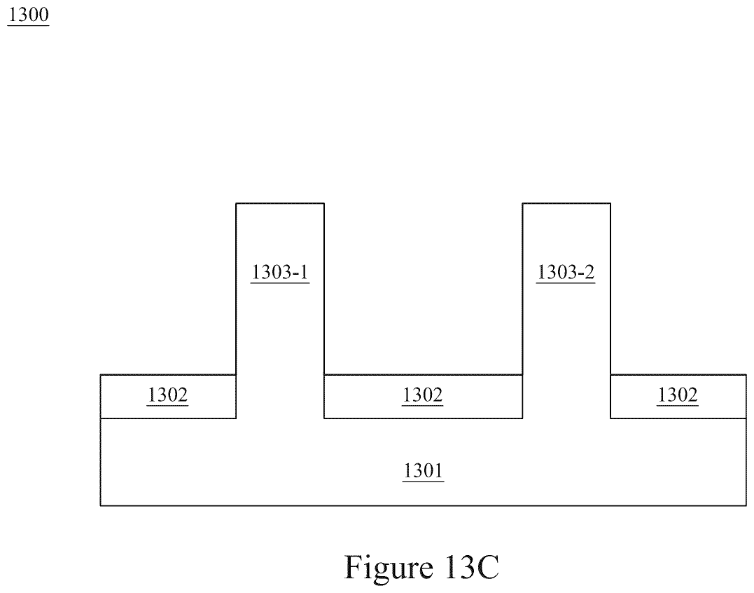

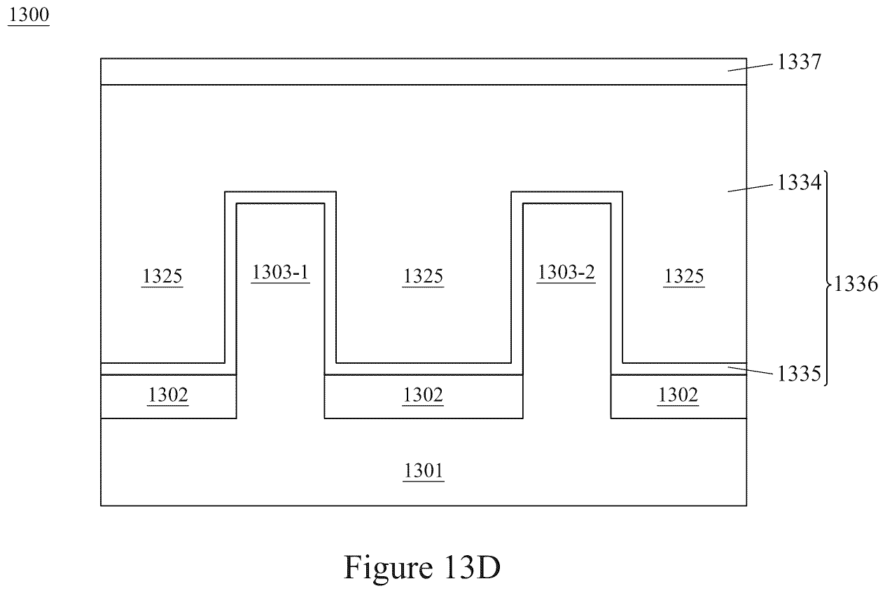

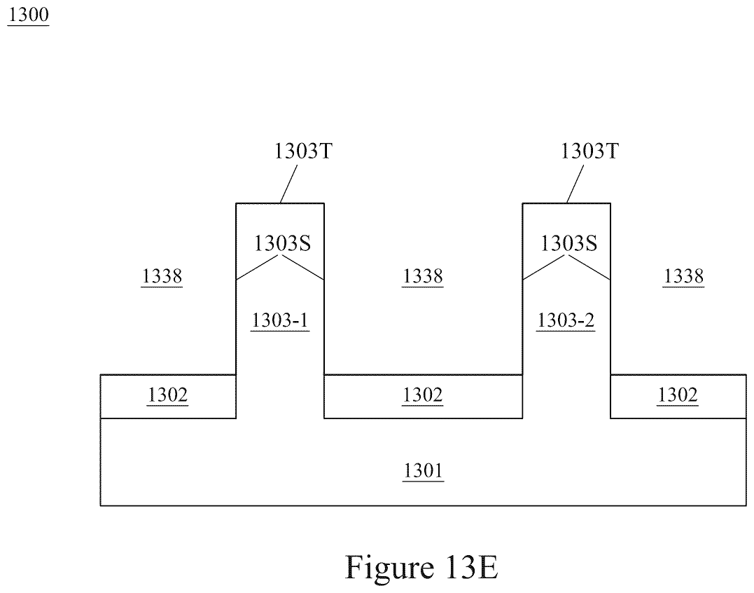

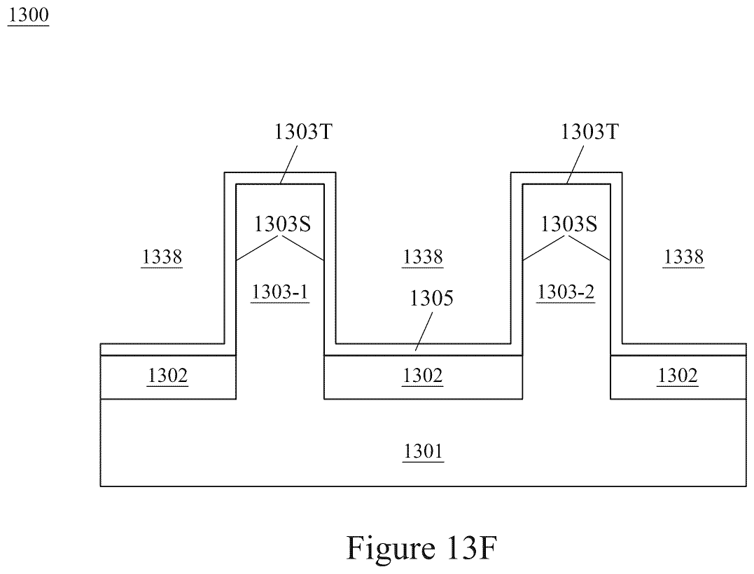

FIG. 12 is provided as a reference to illustrate a number of cross-sections in subsequent figures. For example, cross-section Y-Y′ extends along a longitudinal axis of the gate 1204 of device portion 1200. Cross-section X-X′ is perpendicular to cross-section Y-Y′ and is along a longitudinal axis of the fin 1203 and in a direction of, for example, a current flow between the source/drain structures 1206S/D. FIG. 13A-13F refer to these reference cross-sections.

FIG. 13A-13F each illustrate, in a cross-sectional view, a single gate portion 1300 of at various fabrication stages of the process 210. Portion device 1300 is substantially similar to portion 1200 shown in FIG. 12. Although FIG. 13A-6F illustrate portion 1300 of the FinFET device, it is understood the FinFET device may include a number of other devices such as inductors, fuses, capacitors, coils, etc., which are not shown in FIG. 13A-13F for purposes of clarity of illustration.

FIG. 13A is a cross-sectional view of portion 1300 of the FinFET device including a semiconductor substrate 1301 at one of the various stages of fabrication. The cross-sectional view of FIG. 13A is cut along the lengthwise direction of a gate structure (e.g., cross-section Y-Y′, as indicated in FIG. 12).

The substrate 1301 may be a semiconductor substrate, such as a bulk semiconductor, a semiconductor-on-insulator (SOI) substrate, or the like, which may be doped (e.g., with a p-type or an n-type dopant) or undoped. The substrate 1301 may be a wafer, such as a silicon wafer. Generally, an SOI substrate includes a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 1301 may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GalnAs, GaInP, and/or GaInAsP; or combinations thereof.

FIG. 13B is a cross-sectional view of portion 1300 of the FinFET device including (semiconductor) fin structures 1303-1 and 1303-2 at one of the various stages of fabrication. The cross-sectional view of FIG. 13B is cut along the lengthwise direction of a gate structure (e.g., cross-section Y-Y′, as indicated in FIG. 12).

Although two fin structures are shown in the illustrated embodiment of FIG. 13B (and subsequent FIGS. 13C-13F), it should be appreciated that the FinFET devicecan include any number of fin structures while remaining within the scope of the present disclosure. In some embodiments, the fin structures 1302-1 and 1302-2 are formed by patterning the substrate 1301 using, for example, photolithography and etching techniques. For example, a mask layer, such as a pad oxide layer 1322 and an overlying pad nitride layer 1323, is formed over the substrate 1301. The pad oxide layer 1322 may be a thin film comprising silicon oxide formed, for example, using a thermal oxidation process. The pad oxide layer 1322 may act as an adhesion layer between the substrate 1301 and the overlying pad nitride layer 1323. In some embodiments, the pad nitride layer 1323 is formed of silicon nitride, silicon oxynitride, silicon carbonitride, the like, or combinations thereof. The pad nitride layer 1323 may be formed using low-pressure chemical vapor deposition (LPCVD) or plasma enhanced chemical vapor deposition (PECVD), for example.

The mask layer may be patterned using photolithography techniques. Generally, photolithography techniques utilize a photoresist material (not shown) that is deposited, irradiated (exposed), and developed to remove a portion of the photoresist material. The remaining photoresist material protects the underlying material, such as the mask layer in this example, from subsequent processing steps, such as etching. For example, the photoresist material is used to pattern the pad oxide layer 1322 and pad nitride layer 1323 to form a patterned mask 1324, as illustrated in FIG. 13B.

The patterned mask 1324 is subsequently used to pattern exposed portions of the substrate 1301 to form trenches (or openings) 1325, thereby defining a fin structure (e.g., 1303-1, 1303-2) between adjacent trenches 1325 as illustrated in FIG. 6B. When multiple fin structures are formed, such a trench may be disposed between any adjacent ones of the fin structures. In some embodiments, the fin structures 1303-1 and 1303-2 are formed by etching trenches in the substrate 1301 using, for example, reactive ion etch (RIE), neutral beam etch (NBE), the like, or combinations thereof. The etch may be anisotropic. In some embodiments, the trenches 1325 may be strips (viewed from the top) parallel to each other, and closely spaced with respect to each other. In some embodiments, the trenches 1325 may be continuous and surround each of the fin structures 1303-1 and 1303-2. The fin structures 1303-1 and 1303-2 may sometimes be referred to as fin 1303 hereinafter.

The fin 1303 may be patterned by any suitable method. For example, the fin 1303 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fin.

Each fin 1303 may have a width, i.e. a dimension parallel Y-Y′ direction, from 1 nm to 100 nm or from 2 nm to 70 nm or from 2 nm to 50 nm or from 10 nm to 50 nm or from 2 nm to 10 nm. Each fin 1303 may have a height, i.e. a distance on which it protrudes from the substrate 601, from 5 nm to 200 nm or 5 nm to 100 nm or 10 nm to 200 nm or from 15 nm to 150 nm or from 20 nm to 100 nm.

In certain embodiments, the FinFET device may include multiple types of fins 1303, with fin(s) within each type having at least one dimension, such as a height and/or a width, being different from fin(s) of any other type. For example, in some embodiments, the FinFET device may include (a) smaller fin(s), each having a fin width from 2 nm to 10 nm and a fin height from 20 nm to 100 nm, and (b) larger fin(s), each having a fin width from 10 nm to 50 nm and a fin height from 20 nm to 100 nm.

FIG. 13C is a cross-sectional view of portion 1300 of the FiNFET device including isolation regions 1302 at one of the various stages of fabrication. The cross-sectional view of FIG. 13C is cut along the lengthwise direction of a gate structure (e.g., cross-section Y-Y′, as indicated in FIG. 12).

The isolation regions 1302, which are formed of an insulation material, can electrically isolate neighboring fins from each other. The insulation material may be an oxide, such as silicon oxide, a nitride, the like, or combinations thereof, and may be formed by a high density plasma chemical vapor deposition (HDP-CVD), a flowable CVD (FCVD) (e.g., a CVD-based material deposition in a remote plasma system and post curing to make it convert to another material, such as an oxide), the like, or combinations thereof. Other insulation materials and/or other formation processes may be used. In the illustrated embodiment, the insulation material is silicon oxide formed by a FCVD process. An anneal process may be performed once the insulation material is formed. A planarization process, such as a chemical mechanical polish (CMP), may remove any excess insulation material and form top surfaces of the isolation regions 1302 and a top surface of the fin 1303 that are coplanar (not shown). The patterned mask 1324 (FIG. 13B) may also be removed by the planarization process.

In some embodiments, the isolation regions 1302 include a liner, e.g., a liner oxide (not shown), at the interface between each of the isolation regions 1302 and the substrate 1301 (fin 1303). In some embodiments, the liner oxide is formed to reduce crystalline defects at the interface between the substrate 1301 and the isolation region 1302. Similarly, the liner oxide may also be used to reduce crystalline defects at the interface between the fin 1301 and the isolation region 1302. The liner oxide (e.g., silicon oxide) may be a thermal oxide formed through a thermal oxidation of a surface layer of the substrate 1301, although other suitable method may also be used to form the liner oxide.

Next, the isolation regions 1302 are recessed to form shallow trench isolation (STI) regions 1302, as shown in FIG. 13C. The isolation regions 1302 are recessed such that the upper portions of the fin 1303 protrude from between neighboring STI regions 1302. Respective top surfaces of the STI regions 1302 may have a flat surface (as illustrated), a convex surface, a concave surface (such as dishing), or combinations thereof. The top surfaces of the STI regions 1302 may be formed flat, convex, and/or concave by an appropriate etch. The isolation regions 1302 may be recessed using an acceptable etching process, such as one that is selective to the material of the isolation regions 1302. For example, a dry etch or a wet etch using dilute hydrofluoric (DHF) acid may be performed to recess the isolation regions 1302.

FIG. 13A-C illustrate an embodiment of forming the fin 1303, but a fin may be formed in various different processes. For example, a top portion of the substrate 1301 may be replaced by a suitable material, such as an epitaxial material suitable for an intended type (e.g., N-type or P-type) of semiconductor devices to be formed. Thereafter, the substrate 1301, with epitaxial material on top, is patterned to form the fin 1303 that includes the epitaxial material.

As another example, a dielectric layer can be formed over a top surface of a substrate; trenches can be etched through the dielectric layer; homoepitaxial structures can be epitaxially grown in the trenches; and the dielectric layer can be recessed such that the homoepitaxial structures protrude from the dielectric layer to form one or more fins.

In yet another example, a dielectric layer can be formed over a top surface of a substrate; trenches can be etched through the dielectric layer; heteroepitaxial structures can be epitaxially grown in the trenches using a material different from the substrate; and the dielectric layer can be recessed such that the heteroepitaxial structures protrude from the dielectric layer to form one or more fins.

In embodiments where epitaxial material(s) or epitaxial structures (e.g., the heteroepitaxial structures or the homoepitaxial structures) are grown, the grown material(s) or structures may be in situ doped during growth, which may obviate prior and subsequent implantations although in situ and implantation doping may be used together. Still further, it may be advantageous to epitaxially grow a material in an NMOS region different from the material in a PMOS region. In various embodiments, the fin 1303 may include silicon germanium (SixGe1-x, where x can be between 0 and 1), silicon carbide, pure or substantially pure germanium, a III-V compound semiconductor, a II-VI compound semiconductor, or the like. For example, the available materials for forming III-V compound semiconductor include, but are not limited to, InAs, AlAs, GaAs, InP, GaN, InGaAs, InAlAs, GaSb, AlSb, AlP, GaP, and the like.

FIG. 13D is a cross-sectional view of portion 1300 of the FinFET device including a dummy gate structure 1336 at one of the various stages of fabrication. The cross-sectional view of FIG. 13D is cut along the lengthwise direction of a gate structure (e.g., cross-section Y-Y′, as indicated in FIG. 12).

The dummy gate structure 1336 may include a dummy gate dielectric 1335 and a dummy gate 1334, in some embodiments. A mask 1337 may be formed over the dummy gate structure 1336. To form the dummy gate structure 1336, a dielectric layer is formed on the 1303. The dielectric layer may be, for example, silicon oxide, silicon nitride, multilayers thereof, or the like, and may be deposited or thermally grown.

A gate layer is formed over the dielectric layer, and a mask layer is formed over the gate layer. The gate layer may be deposited over the dielectric layer and then planarized, such as by a CMP. The mask layer may be deposited over the gate layer. The gate layer may be formed of, for example, polysilicon, although other materials may also be used. The mask layer may be formed of, for example, silicon nitride or the like.

After the layers (e.g., the dielectric layer, the gate layer, and the mask layer) are formed, the mask layer may be patterned using acceptable photolithography and etching techniques to form the mask 1337. The pattern of the mask 1337 then may be transferred to the gate layer and the dielectric layer by an acceptable etching technique to form the dummy gate 1334 and the underlying dummy gate dielectric 1335, respectively. The dummy gate 1334 and the dummy gate dielectric 1335 cover a central portion (e.g., a channel region) of the fin 1303. The dummy gate 1336 may also have a lengthwise direction (e.g., direction Y-Y′ of FIG. 12) substantially perpendicular to a lengthwise direction (e.g., direction of X-X′ of FIG. 12) of the fin 1303.

The dummy gate dielectric 1335 is shown to be formed over the fin 1303 (e.g., over top surfaces and sidewalls of each fin structures 1303-1 and 1303-2) and over the STI regions 1302 in the example of FIG. 13D. In other embodiments, the dummy gate dielectric 1335 may be formed by, e.g., thermal oxidization of a material of the fin 1303, and therefore, may be formed over the fin 1303 but not over the STI regions 1302. It should be appreciated that these and other variations are still included within the scope of the present disclosure.

An example gate-last process (sometimes referred to as replacement gate process) is performed subsequently to replace the dummy gate structures 1336 with an active gate structure (which may also be referred to as a replacement gate structure or a metal gate structure). Prior to removing the dummy gate structure 1336, a number of features/structures may have been formed in the FinFET device 600. For example, a gate spacer disposed on sides of the dummy gate structure 1336, source/drain structures formed in the fin 1303 (e.g., on the sides of the dummy gate structure 1336 with the gate spacer disposed therebetween), an interlayer dielectric (ILD) disposed over the source/drain structures, etc.

FIG. 13E is a cross-sectional view of portion 1300 in which the dummy gate structure 1336 is removed to form a gate trench 1338, at one of the various stages of fabrication. The cross-sectional view of FIG. 13E is cut along the lengthwise direction of a dummy or an active gate structure (e.g., cross-section Y-Y′, as indicated in FIG. 12).

To remove the dummy gate structure 1336, one or more etching steps are performed to remove the dummy gate 1334 and then the dummy gate dielectric 1335, so that the gate trench 1338 (which may also be referred to as a recess) is formed. The gate trench 1338 can expose a channel region of the fin structure 1303. During the dummy gate removal, the dummy gate dielectric 1335 may be used as an etch stop layer when the dummy gate 1334 is etched. The dummy gate dielectric 1335 may then be removed after the removal of the dummy gate 1334. Upon removing the dummy gate structure 1336 (or forming the gate trench 1338), a top surface 1303T and sidewalls 13035 of each of the fin structures 1303 can be exposed, which can be better illustrated in the cross-sectional view of FIG. 13.

FIG. 13F is a cross-sectional view of portion 1300 of the FinFET device including a gate dielectric layer 1305, at one of the various stages of fabrication. The cross-sectional view of FIG. 13F is cut along the lengthwise direction of a dummy or an active gate structure (e.g., cross-section Y-Y′, as indicated in FIG. 13).

The gate dielectric layer 1305 is disposed, such as on the top surface and along the sidewalls of each fin structure 1303-1 and 1303-2. In some embodiments, the gate dielectric layer 1305 may include silicon oxide, silicon nitride, or multilayers thereof. In example embodiments, the gate dielectric layer 1305 includes a high-k dielectric material, and in these embodiments, the gate dielectric layer 1305 may have a k value greater than about 7.0, and may include a metal oxide or a silicate of Hf, Al, Zr, La, Mg, Ba, Ti, Pb, and combinations thereof. The formation methods of gate dielectric layer 1305 may include molecular beam deposition (MBD), atomic layer deposition (ALD), PECVD, and the like. A thickness of the gate dielectric layer 1305 may be between about 8 angstroms (Å) and about 20 angstroms, as an example. A thickness of the gate dielectric layer 1305 may be between about 5 nanometer (nm) and about 25 nm, as another example.

One or more metal gate layers may be formed conformally over the gate dielectric layer 1305. One or more metal gate layers may include a barrier layer containing an electrically conductive material such as titanium nitride, although other materials, such as tantalum nitride, titanium, tantalum, or the like, may alternatively be utilized. The barrier layer may be formed using a CVD process, such as PECVD. However, other alternative processes, such as sputtering, metal organic chemical vapor deposition (MOCVD), or ALD, may alternatively be used.

The one or more metal gate layers may also include a work function layer, such as P-type work function layer or N-type work function layer, is formed in the recesses over the barrier layer. Exemplary P-type work function metals that may be included in the gate structures for P-type devices include TiN, TaN, Ru, Mo, Al, WN, ZrSi2, MoSi2, TaSi2, NiSi2, WN, other suitable P-type work function materials, or combinations thereof. Exemplary N-type work function metals that may be included in the gate structures for N-type devices include Ti, Ag, TaAl, TaAlC, TiAlN, TaC, TaCN, TaSiN, Mn, Zr, other suitable N-type work function materials, or combinations thereof. A work function value is associated with the material composition of the work function layer, and thus, the material of the work function layer is chosen to tune its work function value so that a target threshold voltage Vt is achieved in the device that is to be formed. The work function layer(s) may be deposited by CVD, physical vapor deposition (PVD), and/or other suitable process.

The or more metal gate layers may also include a seed layer formed conformally over the work function layer. The seed layer may include copper, titanium, tantalum, titanium nitride, tantalum nitride, the like, or a combination thereof, and may be deposited by ALD, sputtering, PVD, or the like. In some embodiments, the seed layer is a metal layer, which may be a single layer or a composite layer comprising a plurality of sub-layers formed of different materials. For example, the seed layer comprises a titanium layer and a copper layer over the titanium layer.

The or more metal gate layers may also include a gate electrode layer. In some embodiments, the gate electrode layer may be deposited over the seed layer. The gate electrode layer may be made of a metal-containing material such as Cu, Al, W, the like, combinations thereof, or multi-layers thereof, and may be formed by, e.g., electroplating, electroless plating, or other suitable method.

Over the top of the one or more metal gate layers, including the gate electrode layer, a hard mask layer may be formed of, for example, silicon nitride or the like. After the formation of the hard mask layer, the FinFET device may be similar to device 300 in FIG. 3A-C prior to forming opening 313 in its hard mask layer 312.

In one aspect of the present disclosure, a semiconductor device is disclosed. The semiconductor device includes a transistor disposed in an active region. The transistor includes a source/drain feature, a fin channel and a gate structure wrapped over the fin channel. The device further includes an insulation region disposed at an active edge. The active edge is at a boundary of the active region. The insulation region includes a trench. The trench has a tapered portion, so that a width of the tapered portion of the trench at a top of the fin channel is greater than a width of the tapered portion of the trench at a bottom of the gate structure.

In another aspect of the present disclosure, a method is disclosed. The method involves fabricating on a substrate a device including a first transistor in a first active region, a second transistor in a second active region and a sacrificial gate structure at a boundary between the first active region and the second active region. Each of the first transistor, the second transistor and the sacrificial structure include (a) a fin channel extending from the substrate and (b) one or more gate layers over the fin channel. Each of the first transistor and the second transistor further includes a source/drain feature. The method further involves forming a tapered trench at the boundary between the first active region and the second active region. Such forming involves continuously etching the one or more gate layers of the sacrificial gate structure, the fin channel underneath the one or more gate layers of the sacrificial gate structure and a portion of the substrate at the boundary between the first active region and the second active region. A width of the trench at a top of the fin channel is greater than a width of the trench at a bottom of the one or more gate layers of the sacrificial gate structure.

In yet another aspect of the present disclosure, a method of fabricating a semiconductor device is disclosed. The method involves providing a sacrificial structure on a substrate, the sacrificial structure comprises (a) a fin channel extending from the substrate and (b) one or more gate layers wrapping over the fin channel. The sacrificial structure is disposed at an active edge adjacent to an active region. The method further involves continuously etching the one or more gate layers of the sacrificial structure, the fin channel of the sacrificial structure and a portion of the substrate underneath the sacrificial structure to form a trench having a tapered profile. A width of the trench at a top of the fin channel is greater than a width of the trench at a bottom of the one or more gate layers. The etching does not damage a source/drain feature within the adjacent active region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
a transistor disposed in an active region, wherein the transistor comprises a source/drain feature, a fin channel and a gate structure wrapping over the fin channel; and
an insulation region disposed at an active edge, the active edge being at a boundary of the active region, wherein the insulation region includes a trench; wherein the trench has a tapered portion, so that a width of the tapered portion of the trench at a top of the fin channel is greater than a width of the tapered portion of the trench at a bottom of the gate structure.

2. The semiconductor device of claim 1, wherein the transistor comprises a FinFET transistor.

3. The semiconductor device of claim 1, further comprising a substrate, wherein the active region is disposed on a surface of the substrate so that the fin channel extends from the surface of the substrate and wherein the tapered portion of the trench extends into the substrate.

4. The semiconductor device of claim 1, wherein the trench is filled with a dielectric material.

5. The semiconductor device of claim 4, wherein the dielectric material is silicon nitride.

6. A method comprising:
fabricating on a substrate a device comprising a first transistor in a first active region, a second transistor in a second active region and a sacrificial gate structure at a boundary between the first active region and the second active region; each of the first transistor, the second transistor and the sacrificial gate structure comprises (a) a fin channel extending from the substrate and (b) one or more gate layers over the fin channel, each of the first transistor and the second transistor further comprises source/drain feature; and
forming a tapered trench at the boundary between the first active region and the second active region, wherein said forming comprises continuously etching the one or more gate layers of the sacrificial gate structure, the fin channel underneath the one or more gate layers of the sacrificial gate structure and a portion of the substrate at the boundary between the first active region and the second active region, wherein a width of the trench at a top of the fin channel is greater than a width of the trench at a bottom of the one or more gate layers of the sacrificial gate structure.

7. The method of claim 6, wherein said etching is dry etching.

8. The method of claim 6, wherein the one or more gate layers over the fin channel of the sacrificial gate structure comprise a metal gate layer and a dielectric gate layer and wherein said continuously etching comprises etching the metal gate layer and the dielectric gate layer.

9. The method of claim 8, wherein a portion of the metal gate layer and the dielectric gate layer along a tapered wall of the trench remains intact upon said etching.

10. The method of claim 8, wherein the dielectric gate layer comprises a high-K dielectric gate layer.

11. The method of claim 6, further comprising filling the tapered trench with a dielectric material.

12. The method of claim 11, wherein the dielectric material is silicon nitride.

13. The method of claim 6, wherein each of the first transistor and the second transistor comprises a FinFET transistor.

14. A method of fabricating a semiconductor device, comprising:
providing a sacrificial structure on a substrate, the sacrificial structure comprises (a) a fin channel extending from the substrate and (b) one or more gate layers wrapping over the fin channel, the sacrificial structure is disposed at an active edge adjacent to an active region, and
continuously etching the one or more gate layers of the sacrificial structure, the fin channel of the sacrificial structure and a portion of the substrate underneath the sacrificial structure to form a trench having a tapered profile, so that a width of the trench at a top of the fin channel is greater than a width of the trench at a bottom of the one or more gate layers, and wherein said etching does not damage a source/drain feature within the adjacent active region.

15. The method of claim 14, wherein said etching is dry etching.

16. The method of claim 14, wherein the one or more gate layers over the fin channel of the sacrificial structure comprises a metal gate layer and a dielectric gate layer and wherein said etching comprises etching the metal gate layer and the dielectric gate layer.

17. The method of claim 16, wherein a portion of the metal gate layer and the dielectric gate layer along a tapered wall of the trench remains intact upon said etching.

18. The method of claim 16, wherein the dielectric gate layer comprises a high-K dielectric gate layer.

19. The method of claim 14, further comprising filling the trench with a dielectric material.

20. The method of claim 14, wherein the dielectric material is silicon nitride.
